(19) United States
(12) Patent Application Publication
(10) Pub. No.: US 2026/0130262 A1
(43) Pub. Date: May 7, 2026

(54) CONNECTIVITY METHOD AND STRUCTURE FOR 3D-CHIPLET STACKS FOR POWER; GROUND; AND LIMITED SIGNALS

(71) Applicant: Intel Corporation, Santa Clara, CA (US)

(72) Inventors: Stephen MOREIN, San Jose, CA (US); Casey THIELEN, Chandler, AZ (US); Terry William GILMORE, Ridgefield, WA (US)

(21) Appl. No.: 19/426,119

(22) Filed: Dec. 19, 2025

Related U.S. Application Data
(60) Provisional application No. 63/827,012, filed on Jun. 20, 2025.

(51) Int. Cl. H10W 72/00; H10W 72/90; H10W 90/20

(52) U.S. Cl. CPC H10W 72/834; H10W 72/874; H10W 72/944; H10W 90/20

(57) ABSTRACT

A device may include a plurality of chiplets stacked on top of each other. Each chiplet includes: one or more electronic components; a plurality of connections electrically connecting the one or more electronic components, the plurality of connections formed in one or more metal layers; main surfaces and side surfaces, wherein the main surfaces of adjacent chiplets of the plurality of chiplets face each other. The device may further include an electrically conductive connection formed on at least one side surface of at least one chiplet of the plurality of chiplets to electrically connect one or more connections of the plurality of connections of one or more chiplets of the plurality of chiplets.

### CROSS-REFERENCE TO RELATED APPLICATION

Priority is claimed as nonprovisional of U.S. 63/827,012 filed on Jun. 20, 2025.

### BACKGROUND

With a 3D chiplet stack, power and ground connections need to be created for every die. That takes precious connections from the base of the 3D chiplet stack that could otherwise support data bandwidth and signaling in general. If the 3D chiplet stack is rotated on-edge, the connections to the substrate base are likely more difficult to support from all the chiplets in the stack, and power especially can suffer from the longer physical length or restricted width of the connections.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts a 3D chip stack including a plurality of chiplets according to an embodiment;

FIG. 2 depicts another 3D chip stack including a plurality of chiplets according to an embodiment;

FIG. 3 depicts a flow diagram illustrating a method of manufacturing an electrically conductive connection formed on a side surface of one or more chiplets of a chiplet stack including a plurality of chiplets;

FIGS. 4A to 4E depict a method of manufacturing a device according to an embodiment; and

FIG. 5 depicts a device according to an embodiment.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [. . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [. . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

If the 3D chiplet stack is rotated on-edge, the connections to the substrate base are likely more difficult to support from all the chiplets in the stack, and power especially can suffer from the longer physical length or restricted width of the connections. Various embodiments address that bottleneck.

By creating pads or busbars around the sides of a 3D (3-dimensional) chiplet stack (also referred to as chiplet stack) that connect into electrical planes or connections on each layer of the 3D chiplet stack, power and ground can more easily connect to each chiplet of the 3D chiplet stack without needing to route through the substrate at the base of the chiplet stack. Creating the electrically isolated pads physically on the sides (and even potentially on the top) of the chiplet stack allows power to connect into the chiplet stack directly to each chiplet. This is true also for a limited number of general-purpose signals (e.g. “GPIO” (General Purpose Input Output) signals such as test signals, functional signals, or debug signals) as well as the ground connection that would primarily support power and those GPIO signals.

This provides a more direct power/ground connection to each chiplet of the chiplet stack, allowing for better I²R losses and lower voltage drop, as well as a higher current carrying capability to each chiplet of the chiplet stack. Furthermore, this frees up electrical connections to the substrate that can be used to support greater signal count and corresponding bandwidth.

The embodiments will be described mainly with respect to the following two aspects:
a method of pad creation (in general a creation of an electrically conductive connection) on an (outer) side surface of the chiplets of the 3D chiplet stack;
a use of electrical connections on a 3D chiplet stack that uses the sides and optionally even the top of the stack for connection to bring power, ground and optionally some signals into the 3D chiplet stack, allowing the bottom connections through the base die in the 3D chiplet stack.

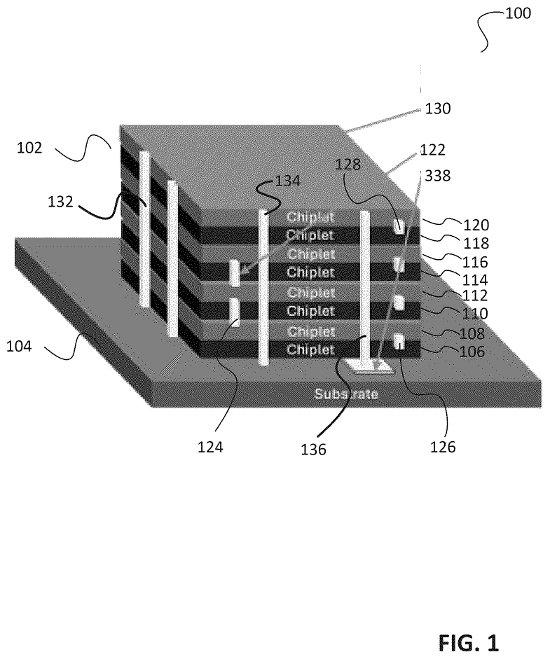

FIG. 1 shows a device 100 including a 3D chiplet stack 102 and a substrate 104. The chiplet stack 102 includes a plurality of (multiple) chiplets 106, 108, 110, 112, 114, 116, 118, 120 with a single base-die (e.g. the bottommost chiplet 106 of the plurality of chiplets 106, 108, 110, 112, 114, 116, 118, 120) connected to the substrate 104. In general, the plurality of chiplets 106, 108, 110, 112, 114, 116, 118, 120 may include an arbitrary number of chiplets, e.g. four, five, six, seven, eight, nine, ten, more than ten, up to 15, more than 15, up to 20, more than 20, up to 30, more than 30, up to 50, more than 50, up to 70, more than 70, up to 100, or even more.

Each chiplet of the plurality of chiplets 106, 108, 110, 112, 114, 116, 118, 120 may include:
one or more electronic components (e.g. any kind of logic circuit such as e.g. a processor, or any kind of memory circuit);
a plurality of connections electrically connecting the one or more electronic components within the chiplet, the plurality of connections formed in one or more metal layers (the plurality of connections may also provide a connection interface to another chiplet or to one or more electrically conductive connections as will be described in more detail below, e.g. to receive power, connect to a reference potential (e.g. ground potential) or receive or provide e.g. test signals, functional signals, or debug signals);
main surfaces (e.g. two main surfaces disposed at opposite sides of the chiplet) and side surfaces (e.g. four side surfaces disposed between the two main surfaces), wherein the main surfaces of adjacent chiplets of the plurality of chiplets 106, 108, 110, 112, 114, 116, 118, 120 face each other.

A memory circuit may include or be a volatile memory circuit, for example a DRAM (Dynamic Random Access Memory) or a non-volatile memory circuit, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory), and the like.

The device 100 may further include an electrically conductive connection formed on at least one side surface of at least one chiplet of the plurality of chiplets to electrically connect one or more connections of the plurality of connections of one or more chiplets of the plurality of chiplets. The electrically conductive connection may include one or more contact pads 122, 124, 126, 128 and/or one or more bus bars 130, 132, 134, 136. The electrically conductive connection may be made of one or more (e.g. a stack of a plurality of) metals or metal alloys. By way of example, the electrically conductive connection may include gold (e.g. as the outermost metal). It is to be noted that the device 300 shown in FIG. 1 is only exemplary and not necessarily to scale.

As shown in FIG. 1, the substrate 104 is not required to connect directly to the chiplet stack 102 for power transport, nor for signal connections, though it can still be used when desired with various embodiments. These signals, e.g. power signals and a connection to a reference potential such as a ground connection, may be provided via the electrically conductive connection formed on at least one side surface of at least one chiplet and this illustratively formed on at least one side surface of the chiplet stack 102. The substrate 104 may include one or more contact pads 138 electrically connected to the electrically conductive connection of the device 100 such as e.g. to the one or more contact pads 122, 124, 126, 128 and/or to the one or more bus bars 130, 132, 134, 136, e.g. via a solder connection (e.g. via a solder ball connection).

Illustratively, FIG. 1 shows a plurality of metal patterns (e.g. gold patterns) on the chiplet stack 102 forming the electrically conductive connection.

It is to be noted that a mechanical cover (such as e.g. a lid, a stiffener or any other mechanical covering) may be disposed over the top of the chiplet stack 102 (facing away from the substrate 104).

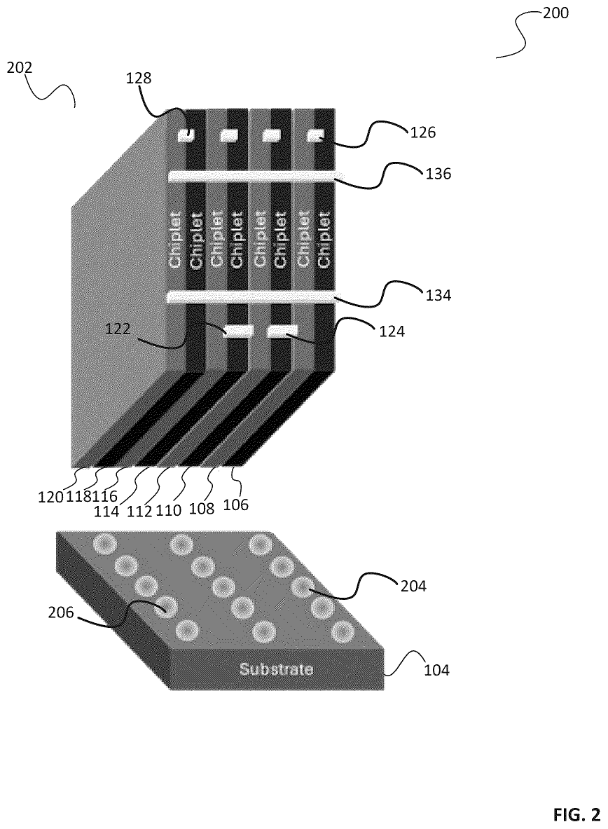

FIG. 2 depicts another device 200 having another 3D chiplet stack 202 including a plurality of chiplets according to an embodiment. The device 200 of FIG. 2 is similar to the device of FIG. 1 with the difference that the chiplet stack 202 being rotated by 90 degrees as compared to the chiplet stack 102 of FIG. 1 with respect to the substrate 104. FIG. 2 further shows that the substrate 104 may include a plurality of contact pads 204, 206, to electrically connect to the plurality of chiplets 106, 108, 110, 112, 114, 116, 118, 120 of the chiplet stack 202. Thus, the plurality of chiplets 106, 108, 110, 112, 114, 116, 118, 120 of the chiplet stack 202 may connect to the substrate 104 with an electrical connection such as solder attach, capacitive or inductive pads, and the like.

The device 200 provides a 3D chiplet stack 202 that is rotated 90 degrees, allowing multiple chiplets 106, 108, 110, 112, 114, 116, 118, 120 of the chiplet stack 202 to physically attach to the substrate 104. This variation of the 3D chiplet stack 202 shows that various embodiments can work equally well with either concept.

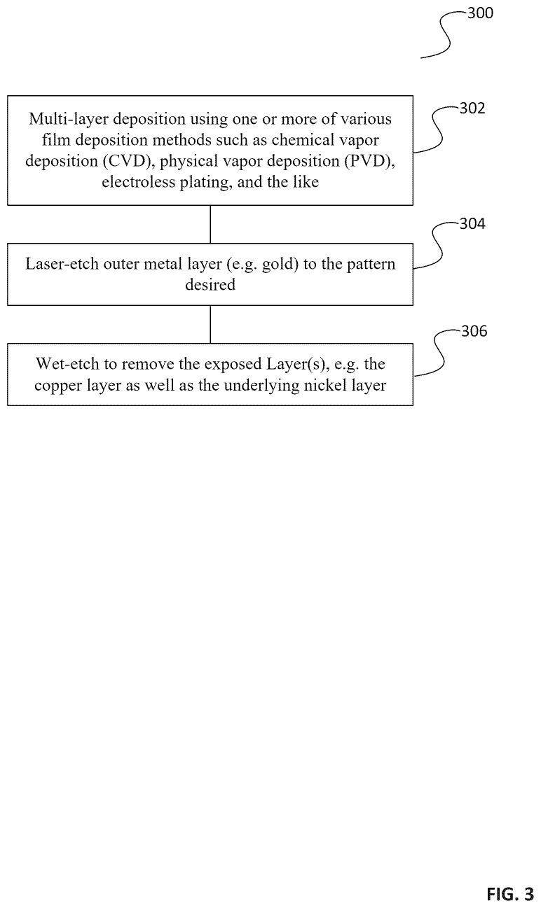

FIG. 3 depicts a flow diagram illustrating a method 300 of manufacturing an electrically conductive connection formed on a side surface of one or more chiplets of a chiplet stack including a plurality of chiplets. In short, a connectivity method for 3D-chiplet stacks for power, ground, and limited signals is provided.

In various aspects, multiple metal layers may be used to create contact pads or busbars or other types of patterned metal on one or more exposed sides of the chiplet stack (e.g. chiplet stack 102, 202).

The method 300 may include, in 302, multi-layer deposition using one or more of various film deposition methods such as chemical vapor deposition (CVD), physical vapor deposition (PVD), electroless plating, and the like. The metal layers may include or be nickel, copper and gold, e.g. in that deposition order.

The outer metal layer may be gold which may then be laser-etched (or sawn) to the pattern desired in 304. This laser etch can partially etch e.g. the copper layer and even into the nickel layer as long as it does not fully etch through both. The gold illustratively acts as an etch mask for subsequent etching steps of the underlying metal layers (e.g. the copper layer and the nickel layer).

The method 300 may further subsequently include, in 306, wet-etching to remove the exposed layer(s), e.g. the copper layer as well as the underlying nickel layer, which is subsequently exposed following the etch of the copper layer.

What is left may be the (e.g. gold) contact pads over the copper and nickel in the areas that are to be electrically connected on the sidewalls (in other words side surfaces) of the plurality of chiplets of the chip stack 102, 202. This could allow contact pads or busbars to wrap around the sidewalls (in other words side surfaces) and even wrap around to the top of the chiplet stack 102, 202, if desired.

It is to be noted that the outer metal (e.g. gold) may act as a hard mask for the wet etch. Additionally, by way of example, the etching pattern can be used to control large etch areas by limiting the exposed copper/nickel and allowing the thinned gold patterns to be lifted off, accomplishing the same large area etch with controlled etch rate and undercut of the copper and nickel that is desired to remain.

A method of manufacturing a device will now be described in more detail.

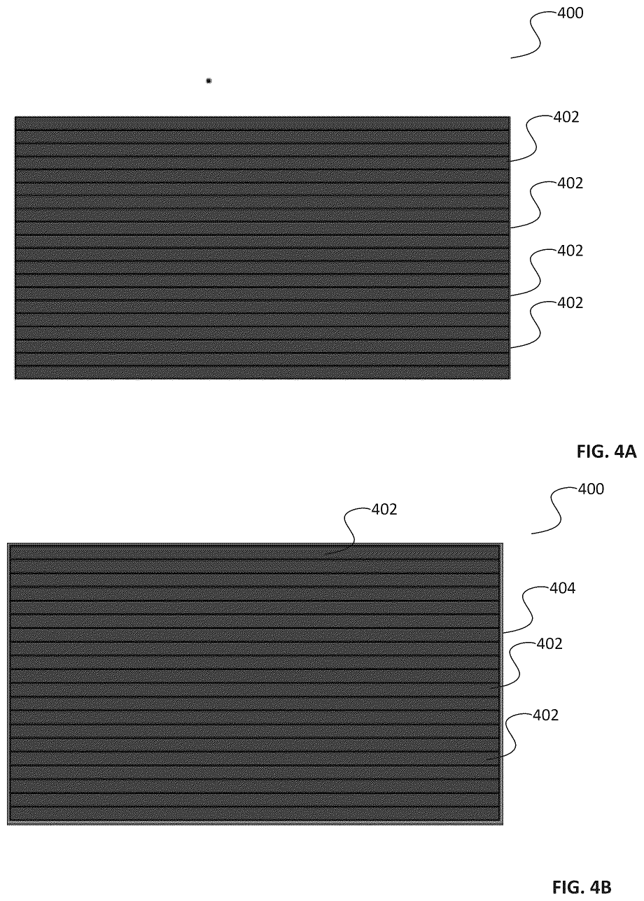

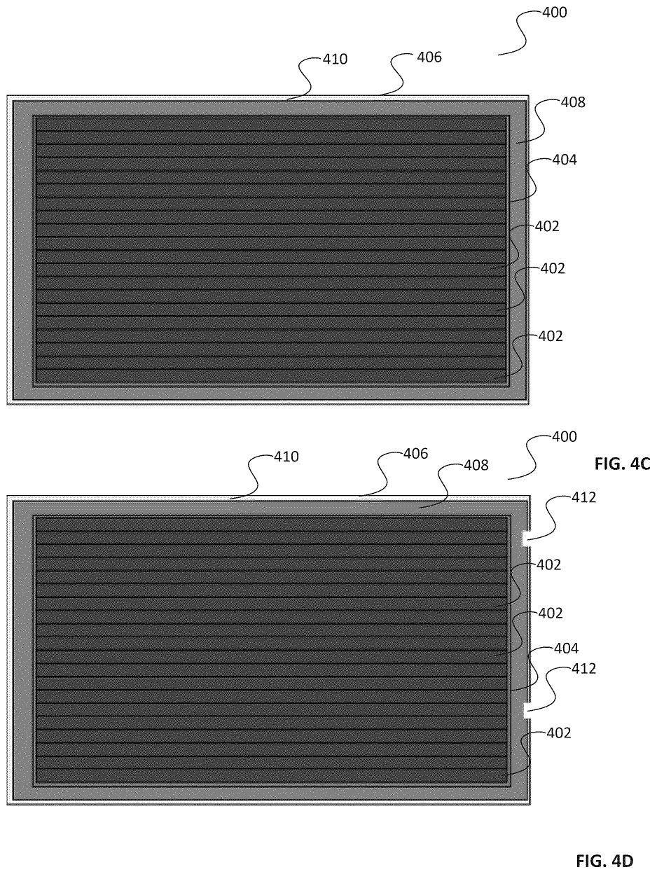

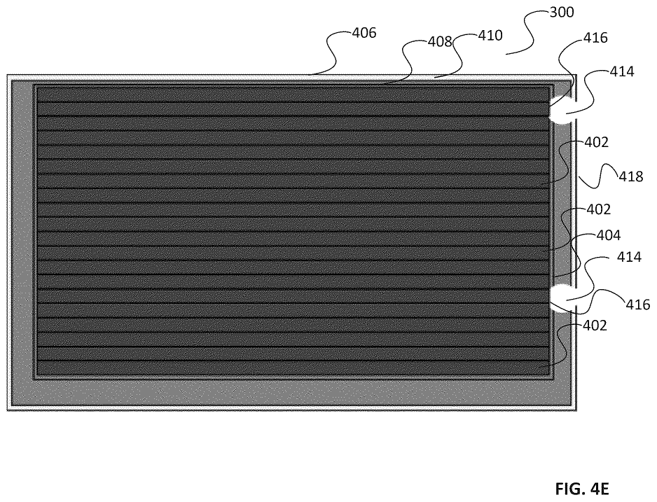

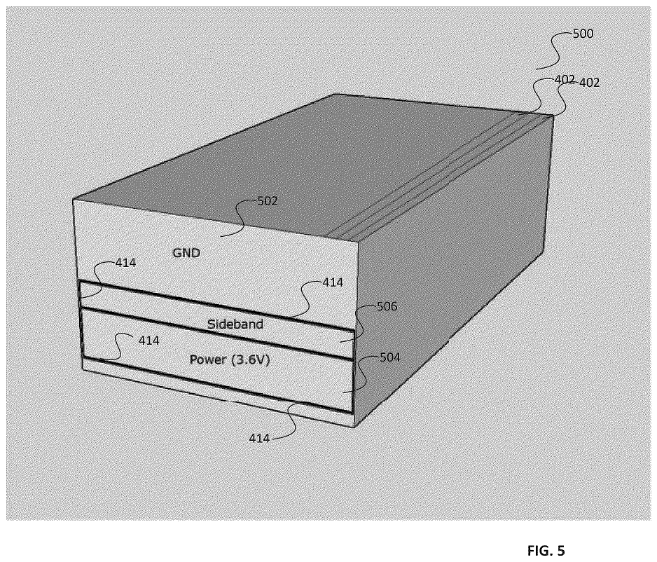

FIG. 4A to FIG. 4E depict a method of manufacturing a device according to an embodiment.

FIG. 4A shows a side view of a stack 400 of a plurality of carriers, e.g. chiplets 402, which may be similar to the stack 102 of chiplets as shown in FIG. 1. As described above, each carrier 402 may have one or more metal layers implementing a plurality of connections electrically connecting the one or more electronic components of the carriers 402. The carriers 402 may be stacked on top of each other. Each carrier 402 may have two main surfaces and four side surfaces.

As shown in FIG. 4B, to form a layer stack 406 including a plurality of layers of electrically conductive material on one or more side surfaces of one or more carriers 402, a seed layer 404 may be deposited (e.g. using physical vapor deposition (PVD)) on one or more side surfaces of at least one carrier 402, e.g. on all side surfaces of all carriers 402 of the stack 400 and thus illustratively on the side surfaces of the stack 400. The seed layer 404 may be a metal seed layer including or essentially consisting of a metal such as e.g. copper.

In various aspects, a first metal layer 408 may be formed on one or more side surfaces of one or more carriers, e.g. on the seed layer 404. The first metal layer 408 may include or essentially consist of copper. A second metal layer 410 may be formed on the first metal layer 408. In case the second metal layer 410 is the outermost metal layer of the layer stack 406, the second metal layer 410 may include or essentially consist of platinum or gold. However, in various aspect, a third layer may be formed on the second metal layer 410. In this case, the second metal layer 410 may include or essentially consist of nickel and the third metal layer (not shown in FIG. 4C) may include or essentially consist of platinum or gold.

It should be noted that other metals may be used to form the layer stack 406.

Then, as shown in FIG. 4D, one or more openings 412 may be formed in the layer stack 406 through the outermost metal layer 410 (e.g. the second metal layer 410 or the third metal layer) into the first metal layer 408 (or the second metal layer, in case a third or one or more additional layers are provided in the layer stack 406). Thus, some metal remains below the openings 412 and such between the bottom of the openings 412 and the side surfaces of the one or more carriers 402. The openings 412 may be formed e.g. by means of laser etching (or by sawing) or by means of any mechanical process. Illustratively, the outermost metal layer 410 may be scored.

As shown in FIG: 4E, the openings 412 may be extended (to form extended openings 414), e.g. by means of wet etching, using the remaining portions of the outermost layer 410 (e,g, a gold layer), as a hard mask for the wet etching. In other words, a portion of the layer stack below the opening 412 is removed using the outermost layer 410 as a mask to expose a portion of a side surface 416 of the one or more carriers 402. A remaining portion of the layer stack 418 forms an electrically conductive connection 418 to electrically connect the one or more connections of the plurality of connections of one or more carriers.

In various aspects, the electrically conductive connection may include a plurality of electrically conductive connection portions which may be isolated from each other to allow the application of different electrical signals to the electrical components of the carriers, such as e.g. a power signal, a reference potential (e.g. ground potential), and/or another electrical signal (e.g. a test signal, a functional signal, or a debug signal).

FIG. 5 depicts a device 500 according to an embodiment. The device 500 may include a first electrically conductive connection portion (e.g. a first busbar) 502 configured to connect a ground potential to the respective desired one or more connections of the plurality of connections of the carriers 402 (e.g. the chiplets 402). The device 500 may further include a second electrically conductive connection portion (e.g. a second busbar) 504 configured to connect a power signal to the respective desired one or more connections of the plurality of connections of the carriers 402 (e.g. the chiplets 402). The device 500 may further include a third electrically conductive connection portion (e.g. a third busbar) 506 configured to connect a sideband signal (e.g. a test signal, a functional signal, or a debug signal) to the respective desired one or more connections of the plurality of connections of the carriers 402 (e.g. the chiplets 402). The first electrically conductive connection portion 502, the second electrically conductive connection portion 504 and the third electrically conductive connection portion may be electrically isolated by each other, e.g. by the extended openings 414.

By way of example, the device 500 may have a size of approximately 6 mm*12 mm*4 mm.

One advantage of the above process may be seen in that it is compatible with batch processing. This may be important in creating a process that is compatible with high-volume manufacturing.

Additional aspects of the description will be disclosed by way of example:

Example 1 is a device. The device may include a plurality of chiplets stacked on top of each other. Each chiplet includes: one or more electronic components; a plurality of connections electrically connecting the one or more electronic components, the plurality of connections formed in one or more metal layers; main surfaces and side surfaces, wherein the main surfaces of adjacent chiplets of the plurality of chiplets face each other. The device may further include an electrically conductive connection formed on at least one side surface of at least one chiplet of the plurality of chiplets to electrically connect one or more connections of the plurality of connections of one or more chiplets of the plurality of chiplets.

In Example 2, the subject matter of Example 1 can optionally include that the electrically conductive connection comprises a contact pad electrically connected to one or more connections of the plurality of connections of one or more chiplets of the plurality of chiplets.

In Example 3, the subject matter of Example 2 can optionally include that the contact pad is electrically connected to one or more electronic components via the one or more connections to provide electrical power to the one or more electronic components.

In Example 4, the subject matter of any one of Examples 2 or 3 can optionally include that the contact pad is electrically connected to one or more electronic components via the one or more connections to provide an electrical reference potential to the one or more electronic components.

In Example 5, the subject matter of Example 4 can optionally include that the contact pad is electrically connected to one or more electronic components via the one or more connections to provide a ground potential to the one or more electronic components.

In Example 6, the subject matter of Example 3 can optionally include that the contact pad is configured as a general purpose input output interface.

In Example 7, the subject matter of any one of Examples 3 or 6 can optionally include that the contact pad is electrically connected to one or more electronic components via the one or more connections to provide a test signal, a functional signal, or a debug signal to the one or more electronic components.

In Example 8, the subject matter of any one of Examples 1 to 7 can optionally include that the electrically conductive connection includes a bus bar electrically connected to one or more connections of the plurality of connections of one or more chiplets of the plurality of chiplets.

In Example 9, the subject matter of Example 8 can optionally include that the bus bar is electrically connected to one or more electronic components via the one or more connections to provide electrical power to the one or more electronic components.

In Example 10, the subject matter of any one of Examples 8 or 9 can optionally include that the bus bar is electrically connected to one or more electronic components via the one or more connections to provide an electrical reference potential to the one or more electronic components.

In Example 11, the subject matter of Example 10 can optionally include that the bus bar is electrically connected to one or more electronic components via the one or more connections to provide a ground potential to the one or more electronic components.

In Example 12, the subject matter of Example 8 can optionally include that the bus bar is configured as a general purpose input output interface.

In Example 13, the subject matter of any one of Examples 8 or 12 can optionally include that the bus bar is electrically connected to one or more electronic components via the one or more connections to provide a test signal, a functional signal, or a debug signal to the one or more electronic components.

In Example 14, the subject matter of any one of Examples 1 to 13 can optionally include that the device further includes a substrate; wherein the plurality of chiplets are disposed over the substrate; and wherein the substrate is electrically connected to the electrically conductive connection.

In Example 15, the subject matter of Example 14 can optionally include that the substrate includes a grounding structure electrically coupled to the electrically conductive connection.

In Example 16, the subject matter of any one of Examples 1 to 15 can optionally include that the device further includes a power source electrically coupled to the electrically conductive connection.

In Example 17, the subject matter of any one of Examples 1 to 16 can optionally include that the device further includes encapsulating material at least partially encapsulating the plurality of chiplets and the electrically conductive connection.

In Example 18, the subject matter of any one of Examples 1 to 17 can optionally include that the one or more electronic components includes at least one of the following components: a logic circuit, e.g. a processor; and a memory circuit.

In Example 19, the subject matter of any one of Examples 1 to 18 can optionally include that the electrically conductive connection includes a portion formed on an outer main surface of a topmost chiplet or bottommost chiplet of the plurality of chiplets.

Example 20 is a method of manufacturing a device. The method may include forming a layer stack comprising a plurality of layers of electrically conductive material on one or more side surfaces of one or more carriers. Each carrier includes one or more electronic components; a plurality of connections electrically connecting the one or more electronic components, the plurality of connections formed in one or more metal layers; main surfaces and side surfaces. The method may further include the one or more layers of electrically conductive material are electrically coupled to the one or more connections of the plurality of connections of one or more carriers; forming one or more openings through the outermost layer of the layer stack; removing a portion of the layer stack below the opening using the outermost layer as a mask to expose a portion of a side surface of the one or more carriers so that a remaining portion of the layer stack forms an electrically conductive connection to electrically connect the one or more connections of the plurality of connections of one or more carriers.

In Example 21, the subject matter of Example 20 can optionally include that the one or more carriers include a plurality of carriers stacked on top of each other; and that the main surfaces of adjacent carriers of the plurality of chiplets face each other.

In Example 22, the subject matter of any one of Examples 20 or 21 can optionally include that the one or more carriers include one or more chiplets,

In Example 23, the subject matter of any one of Examples 20 to 22 can optionally include that forming the layer stack includes forming a layer stack including a plurality of metal layers.

In Example 24, the subject matter of any one of Examples 20 to 23 can optionally include that the plurality of metal layers includes a metal selected from a group of metals consisting of: copper; nickel; platinum; and gold.

In Example 25, the subject matter of any one of Examples 20 to 24 can optionally include that forming the layer stack includes: forming a first metal layer on one or more side surfaces of one or more carriers; and forming a second metal layer on the first metal layer.

In Example 26, the subject matter of Example 25 can optionally include that forming the layer stack further includes forming a third metal layer on the second metal layer.

In Example 27, the subject matter of any one of Examples 25 or 26 can optionally include that the first metal layer includes or essentially consists of copper.

In Example 28, the subject matter of any one of Examples 25 to 27 can optionally include that the second metal layer includes or essentially consists of nickel or platinum or gold.

In Example 29, the subject matter of any one of Examples 26 to 28 can optionally include that the third metal layer includes or essentially consists of platinum or gold.

In Example 30, the subject matter of any one of Examples 20 to 29 can optionally include that forming the layer stack includes: depositing a seed layer on one or more side surfaces of one or more carriers; and forming the first metal layer on the seed layer.

In Example 31, the subject matter of any one of Examples 20 to 30 can optionally include that the one or more openings are formed using a laser;

In Example 32, the subject matter of any one of Examples 20 to 30 can optionally include that the one or more openings are formed by mechanically removing the portion of the outermost layer of the layer stack;

In Example 33, the subject matter of any one of Examples 20 to 32 can optionally include that the one or more openings are formed such that some electrically conductive material of the layer stack remains between the one or more openings and the one or more side surfaces of one or more carriers.

In Example 34, the subject matter of any one of Examples 20 to 33 can optionally include that removing the portion of the layer stack below the opening includes wet etching some electrically conductive material of the layer stack using the outermost layer as a mask to expose a portion of a side surface of the one or more carriers.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. A device, comprising,
a plurality of chiplets stacked on top of each other,
wherein each chiplet comprises:
one or more electronic components;
a plurality of connections electrically connecting the one or more electronic components, the plurality of connections formed in one or more metal layers;
main surfaces and side surfaces, wherein the main surfaces of adjacent chiplets of the plurality of chiplets face each other;
an electrically conductive connection formed on at least one side surface of at least one chiplet of the plurality of chiplets to electrically connect one or more connections of the plurality of connections of one or more chiplets of the plurality of chiplets.

2. The device of claim 1,
wherein the electrically conductive connection comprises a contact pad electrically connected to one or more connections of the plurality of connections of one or more chiplets of the plurality of chiplets.

3. The device of claim 2,
wherein the contact pad is electrically connected to one or more electronic components via the one or more connections to provide electrical power to the one or more electronic components.

4. The device of claim 2,
wherein the contact pad is electrically connected to one or more electronic components via the one or more connections to provide at least one of the following group to the one or more electronic components:
an electrical reference potential;
a ground potential;
a test signal;
a functional signal; and
a debug signal.

5. The device of claim 3,
wherein the contact pad is configured as a general purpose input output interface.

6. The device of claim 1,
wherein the electrically conductive connection comprises a bus bar electrically connected to one or more connections of the plurality of connections of one or more chiplets of the plurality of chiplets.

7. The device of claim 6,
wherein the bus bar is electrically connected to one or more electronic components via the one or more connections to provide at least one of the following group to the one or more electronic components:
electrical power;
an electrical reference potential;
a ground potential;
a test signal;
a functional signal; and
a debug signal.

8. The device of claim 6,
wherein the bus bar is configured as a general purpose input output interface.

9. The device of claim 1, further comprising:
a substrate;
wherein the plurality of chiplets are disposed over the substrate;
wherein the substrate is electrically connected to the electrically conductive connection.

10. The device of claim 9,
wherein the substrate comprises a grounding structure electrically coupled to the electrically conductive connection.

11. The device of claim 1, further comprising:
a power source electrically coupled to the electrically conductive connection.

12. The device of claim 1, further comprising:
encapsulating material at least partially encapsulating the plurality of chiplets and the electrically conductive connection.

13. The device of claim 1,
wherein the one or more electronic components comprise at least one of the following components:
a logic circuit, e.g. a processor;
a memory circuit.

14. The device of claim 1,
wherein the electrically conductive connection comprises a portion formed on an outer main surface of a topmost chiplet or bottommost chiplet of the plurality of chiplets.

15. A method of manufacturing a device, the method comprising,
forming a layer stack comprising a plurality of layers of electrically conductive material on one or more side surfaces of one or more carriers, each carrier comprising:
one or more electronic components:
a plurality of connections electrically connecting the one or more electronic components, the plurality of connections formed in one or more metal layers;
main surfaces and side surfaces;
wherein the one or more layers of electrically conductive material are electrically coupled to the one or more connections of the plurality of connections of one or more carriers;
forming one or more openings through the outermost layer of the layer stack;
removing a portion of the layer stack below the opening using the outermost layer as a mask to expose a portion of a side surface of the one or more carriers so that a remaining portion of the layer stack forms an electrically conductive connection to electrically connect the one or more connections of the plurality of connections of one or more carriers.

16. The method of claim 15,
wherein the one or more carriers comprise a plurality of carriers stacked on top of each other;
wherein the main surfaces of adjacent carriers of the plurality of chiplets face each other.

17. The method of claim 15,
wherein the one or more carriers comprise one or more chiplets,

18. The method of claim 15,
wherein the plurality of metal layers comprises a metal selected from a group of metals consisting of:
copper;
nickel;
platinum; and
gold.

19. The method of claim 15,
wherein the one or more openings are formed such that some electrically conductive material of the layer stack remains between the one or more openings and the one or more side surfaces of one or more carriers.

20. The method of claim 15,
wherein the removing the portion of the layer stack below the opening comprises wet etching some electrically conductive material of the layer stack using the outermost layer as a mask to expose a portion of a side surface of the one or more carriers.
